(19) United States
(12) Patent Application Publication
(10) Pub. No.: US 2026/0255771 A1
(43) Pub. Date: Aug. 27, 2026

(54) LIGHT-EMITTING DEVICE AND DISPLAY DEVICE

(71) Applicant: Hubei Sanan Optoelectronics Co., Ltd., Hubei (CN)

(72) Inventors: Qinghe CHEN, Hubei (CN); Jieling WANG, Hubei (CN); Zhen-duan LIN, Hubei (CN); Weihong CHEN, Hubei (CN); Songtao ZHUANG, Hubei (CN); Junpeng SHI, Hubei (CN)

(73) Assignee: Hubei Sanan Optoelectronics Co., Ltd., Hubei (CN)

(21) Appl. No.: 19/547,497

(22) Filed: Feb. 23, 2026

Related U.S. Application Data
(63) Continuation of application No. PCT/CN2023/114516, filed on Aug. 23, 2023.

(51) Int. Cl. H10H 29/85

(52) U.S. Cl. CPC H10H 29/857

(57) ABSTRACT

The present disclosure discloses a light-emitting device and a display device, including: a plurality of light-emitting elements, the plurality of light-emitting elements being spaced apart from one another; a wiring layer, formed on the plurality of light-emitting elements and electrically connected to the light-emitting elements; an insulating layer, formed on the wiring layer, the insulating layer having an opening portion exposing a partial surface of the wiring layer; a protective electrode, formed on the wiring layer and forming an electrical connection with the wiring layer, which may effectively provide anti-oxidation protection for the exposed surface of the wiring layer, so as to form a good contact with the solder paste during subsequent soldering.

### CROSS-REFERENCE TO RELATED APPLICATION

This application is a continuation of international PCT application serial no. PCT/CN2023/114516, filed on Aug. 23, 2023. The entirety of the above-mentioned patent application is hereby incorporated by reference herein and made a part of this specification.

### BACKGROUND

### Technical Field

The present disclosure relates to semiconductor devices, and specifically relates to a light-emitting device and a display device.

### Description of Related Art

By virtue of high reliability, long service life, and low power consumption, LED chips are commonly employed in a variety of fields, including display devices, vehicle lighting fixtures, and general illumination, and may, for example, serve as backlight sources for various display devices. At present, because miniature chips (micro-LED chips, generally less than 100 nm) are exceedingly small in size, the process of picking up the chips and securing them onto a display panel is relatively difficult. Accordingly, an approach is adopted whereby three RGB chips are formed into a unit pixel package, whereby pick-and-place mounting and fixation of the unit pixel onto the display panel is rendered comparatively simple.

However, existing unit pixel packages also present some issues to be resolved. For example, as unit pixels trend toward miniaturization, the difficulty of securing unit pixels to the display substrate increases. An improper configuration of the internal structure of the unit pixel package may result in a reduction in the luminous intensity of the unit pixels or in light-extraction losses; and relatively small light-emitting angles of light-emitting elements within the unit pixel package may cause non-uniform light output of the entire package, and the like. The foregoing issues severely affect the light-extraction efficiency, reliability, and yield of unit pixels, and are problems that urgently require resolution by those skilled in the art.

### SUMMARY

In view of the above-mentioned shortcomings of the related art, the purpose of the present disclosure is to provide a light-emitting device and a display device, so as to improve the transfer yield, light-emitting effect, and reliability of unit pixels.

In order to achieve the above-mentioned purpose and other related purposes, the present disclosure provides a light-emitting device, which includes:
A plurality of light-emitting elements, the plurality of light-emitting elements being spaced apart;
A wiring layer, formed on the plurality of light-emitting elements, and electrically connected to the light-emitting elements;
An insulating layer, formed on the wiring layer, the insulating layer having an opening portion exposing a partial surface of the wiring layer;
A protective electrode, formed on the wiring layer, and forming an electrical connection with the wiring layer.

The present disclosure further provides another light-emitting device, which includes:
A plurality of light-emitting elements, the plurality of light-emitting elements being spaced apart;
A wiring layer, formed on the plurality of light-emitting elements, and electrically connected to the light-emitting elements;
A protective electrode, formed on the wiring layer, and forming an electrical connection with the wiring layer;
An insulating layer, formed on the wiring layer, the insulating layer having an opening portion exposing a surface of the protective electrode;
Wherein, the insulating layer covers a partial surface of the wiring layer, a partial surface and a sidewall of the protective electrode.

According to an aspect of the present disclosure, the present disclosure further provides a display device, the display device includes:

A display substrate;
At least one light-emitting device, disposed on a surface of the display substrate, the light-emitting device forms an electrical connection with the display substrate, and the light-emitting device is the above-mentioned light-emitting device.

Compared with the related art, the light-emitting device and the display device according to the present disclosure have at least the following advantageous effects:

In the present disclosure, the light-emitting device includes a plurality of light-emitting elements, a wiring layer, and an insulating layer. The plurality of light-emitting elements are spaced apart from one another. The wiring layer is formed on the plurality of light-emitting elements and is electrically connected to each light-emitting element. The insulating layer is formed on the wiring layer, and the insulating layer has an opening portion exposing the partial surface of the wiring layer. The protective electrode is formed on the wiring layer and forms an electrical connection with the wiring layer, which may provide effective anti-oxidation protection for the exposed surface of the wiring layer, so as to form good contact with the solder paste during subsequent soldering

The display device according to the present disclosure includes any one of the above-mentioned light-emitting devices, and also has the above-mentioned technical effects.

### BRIEF DESCRIPTION OF THE DRAWINGS

FIG. 1a is a structural top view of a specific embodiment in Embodiment 1 of the present disclosure;

FIG. 1b is a structural top view of a wiring layer of a specific embodiment in Embodiment 1 of the present disclosure;

FIG. 2a is a schematic cross-sectional view taken along line A-A′ of FIG. 1a of an embodiment in Embodiment 1 of the present disclosure;

FIG. 2b is an enlarged view of an area A in FIG. 2a;

FIG. 2c is a schematic cross-sectional view taken along line A-A′ of FIG. 1 of another embodiment in Embodiment 1 of the present disclosure;

FIG. 3 is a structural top view of a specific embodiment in Embodiment 2 of the present disclosure;

FIG. 4a is a schematic cross-sectional view taken along line B-B′ of FIG. 3;

FIG. 4b is a schematic cross-sectional view taken along line C-C′ of FIG. 3;

FIG. 5a to FIG. 5c are structural top views of a plurality of specific embodiments in Embodiment 2 of the present disclosure, respectively;

FIG. 6a to FIG. 6b are structural top views of a plurality of specific embodiments in Embodiment 2 of the present disclosure;

FIG. 7 is a cross-sectional view (taken along line A-A′ of FIG. 1) of a specific embodiment in Embodiment 2 of the present disclosure;

FIG. 8a is a schematic cross-sectional view (taken along line C-C′ of FIG. 3) of a specific embodiment in Embodiment 3 of the present disclosure;

FIG. 8b is a schematic cross-sectional view (taken along line B-B′ of FIG. 3) of a specific embodiment in Embodiment 3 of the present disclosure;

FIG. 9 is a schematic cross-sectional view (taken along line C-C′ of FIG. 3) of another specific embodiment in Embodiment 3 of the present disclosure;

FIG. 10 is a schematic cross-sectional view (taken along line C-C′ of FIG. 3) of yet another specific embodiment in Embodiment 3 of the present disclosure;

FIG. 11 is a schematic cross-sectional view (taken along line C-C′ of FIG. 3) of still another specific embodiment in Embodiment 3 of the present disclosure;

FIG. 12a is a schematic cross-sectional view (taken along line C-C′ of FIG. 3) of a specific embodiment in Embodiment 4 of the present disclosure;

FIG. 12b is a schematic cross-sectional view (taken along line B-B′ of FIG. 3) of a specific embodiment in Embodiment 4 of the present disclosure;

FIG. 13 is a schematic cross-sectional view (taken along line C-C′ of FIG. 3) of another specific embodiment in Embodiment 4 of the present disclosure;

FIG. 14 is a schematic cross-sectional view (taken along line C-C′ of FIG. 3) of yet another specific embodiment in Embodiment 4 of the present disclosure;

FIG. 15 is a schematic cross-sectional view (taken along line C-C′ of FIG. 3) of still another specific embodiment in Embodiment 4 of the present disclosure;

FIG. 16a is a schematic cross-sectional view (taken along line C-C′ of FIG. 3) of a specific embodiment in Embodiment 5 of the present disclosure;

FIG. 16b is a schematic cross-sectional view (taken along line B-B′ of FIG. 3) of a specific embodiment in Embodiment 5 of the present disclosure;

FIG. 17 is a schematic cross-sectional view (taken along line C-C′ of FIG. 3) of another specific embodiment in Embodiment 5 of the present disclosure;

FIG. 18 is a schematic cross-sectional view (taken along line C-C′ of FIG. 3) of yet another specific embodiment in Embodiment 5 of the present disclosure;

FIG. 19 is a schematic cross-sectional view (taken along line C-C′ of FIG. 3) of still another specific embodiment in Embodiment 5 of the present disclosure;

FIG. 20 is a schematic view of a light-emitting angle of a light-emitting element in a light-emitting device described in FIG. 1a and FIG. 2a in Embodiment 1 of the present disclosure;

FIG. 21 is a schematic view of a light-emitting angle of a light-emitting element in a light-emitting device described in FIG. 17 in Embodiment 5 of the present disclosure;

FIG. 22 is a structural view of a display device described in Embodiment 6 of the present disclosure.

List of reference numerals:

| | | | |
|---|---|---|---|
| 100 | transparent layer | 700a | first region |
| 200 | overhead layer | 700b | second region |
| 201 | first surface | 700c | third region |
| 202 | second surface | 800 | insulating layer |
| 203 | groove | 800a | lower surface |
| 300 | adhesive layer | 800b | upper surface |
| 301 | opening | 800c | side surface |
| 400 | angle adjustment layer | 801 | opening portion |
| 401 | first angle adjustment | 802 | notch portion |
| | layer | | |
| 402 | second angle | 900 | protective electrode |
| | adjustment layer | | |
| 403 | third angle adjustment | 900a | first portion |
| | layer | | |
| 501 | first light-emitting | 900b | second portion |
| | element | | |
| 502 | second light-emitting | 910 | first protective |
| | element | | electrode |
| 503 | third light-emitting | 920 | second protective |
| | element | | electrode |
| 504 | first electrode | 930 | third protective |
| | | | electrode |
| 505 | second electrode | 940 | fourth protective |
| | | | electrode |
| 600 | filling layer | 901 | first sidewall |
| 601 | gap | 902 | second sidewall |
| 602 | groove | 903 | third sidewall |
| 610 | first filling structure | 904 | fourth sidewall |
| 620 | second filling structure | 1001 | first side |
| 611 | first sub-layer | 1002 | second side |
| 612 | second sub-layer | X | first direction |
| 700 | wiring layer | Y | second direction |
| 701 | first layer | 001 | first side |
| 702 | second layer | 002 | second side |
| 710 | first sub-wiring | 003 | third side |
| 720 | second sub-wiring | 004 | fourth side |
| 730 | third sub-wiring | 005 | light-emitting |
| | | | module |
| 740 | fourth sub-wiring | 006 | display substrate |

### DESCRIPTION OF THE EMBODIMENTS

The following specific embodiments illustrate the implementation of the present disclosure A person skilled in this technology may easily understand other advantages and efficacy of the present disclosure from the content disclosed in this specification. The present disclosure may also be implemented or applied through other different specific embodiments, and various details in this specification may also be modified or changed based on different viewpoints and applications without departing from the spirit of the present application. It should be noted that, in the case of no conflict, the following embodiments and the features in the embodiments may be combined with each other.

It should be noted that the drawings provided in the embodiments of the present disclosure are only for illustrative purposes to explain the basic concept of the present disclosure. Although the drawings only show the components related to the present disclosure and are not drawn according to the actual number, shape, and size of the components during actual implementation, the form, quantity, and ratio of each component during actual implementation may be changed at will, and the component layout may also be more complex. The structures, proportions, sizes, and the like shown in the drawings of the specification are only used to match the content disclosed in the specification for a person skilled in this technology to understand and read, and are not used to limit the conditions under which the present application may be implemented, and therefore have no technical substantive significance. Any modification of structures, change of proportional relationships, or adjustment of sizes, without affecting the efficacy that the present disclosure may generate and the objectives that may be achieved, should still fall within the scope that the technical content disclosed in the present application is able to cover.

The present embodiment will be described in detail below in conjunction with specific embodiments.

### Embodiment 1

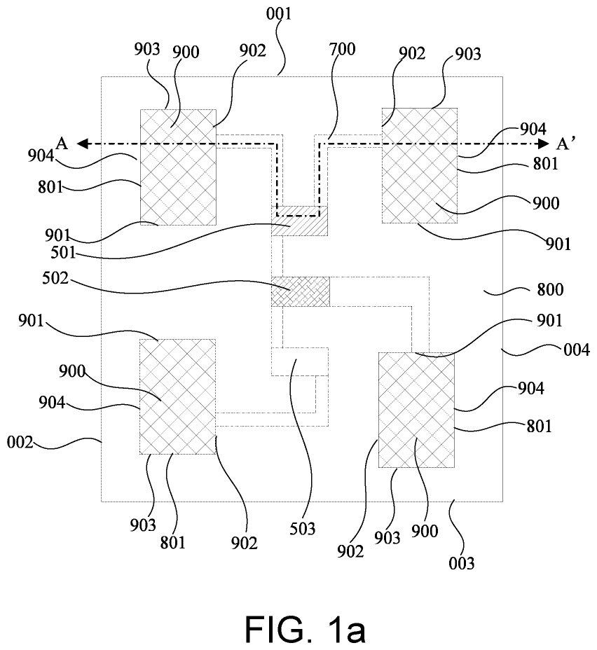

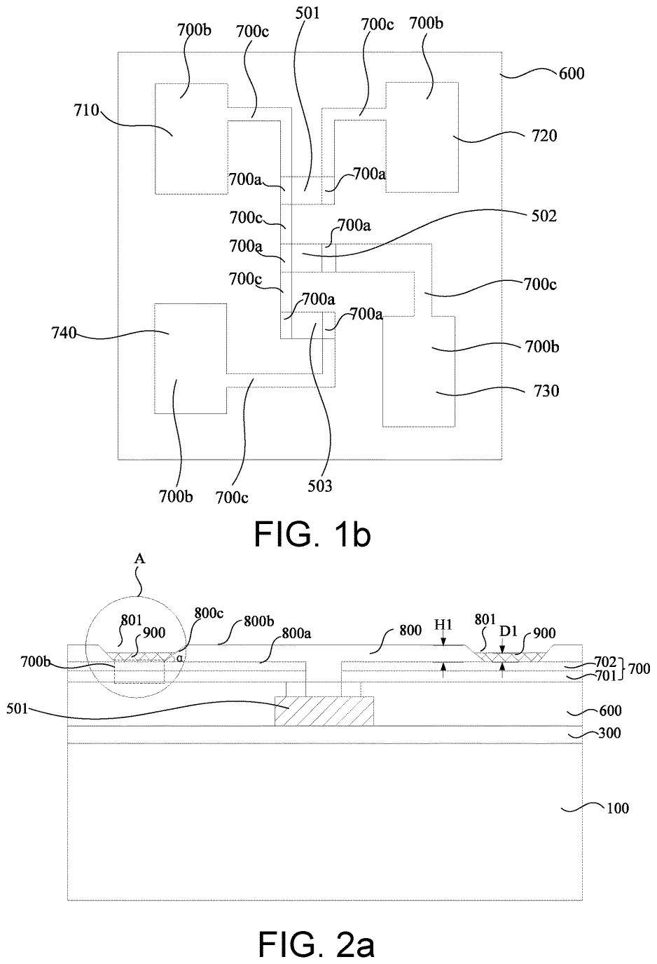

FIG. 1a is a structural top view of a specific embodiment in the present embodiment;

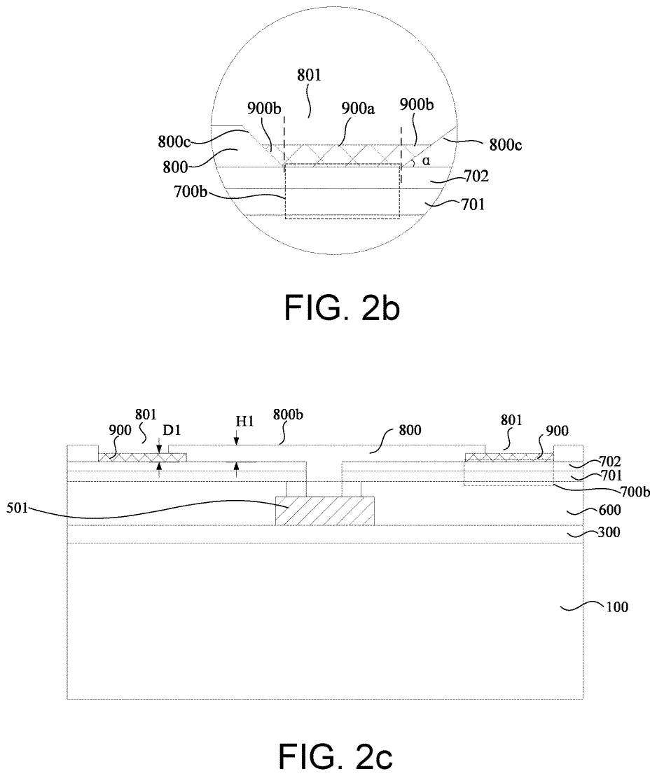

FIG. 2a is a cross-sectional view taken along line A-A′ of FIG. 1a.

The present embodiment provides a light-emitting device. Referring to FIG. 1a and FIG. 2a, the light-emitting device includes a transparent layer 100, a plurality of light-emitting elements, a wiring layer 700, and an insulating layer 800.

Referring to FIG. 1a and FIG. 2a, the transparent layer 100 may have a light transmittance of 60% or more within a visible light range. Optionally, the transparent layer 100 may be a transparent substrate, and the transparent substrate may be a light-transmitting substrate such as PET, glass, quartz, sapphire, transparent ceramic, or the like. The light-emitting device needs to have a specific thickness for use by the client, and therefore a thickness of the transparent layer 100 is preferably greater than 10 μm, specifically preferably 30 μm to 50 μm, 50 μm to 100 μm, or 100 μm to 300 μm. A plurality of light-emitting elements are disposed on a surface of the transparent layer 100. A side of the transparent layer 100 away from the light-emitting elements is a light-emitting surface of the light-emitting device, that is, the light emitted by the light-emitting elements is all emitted outward through the transparent layer 100.

Referring to FIG. 2a, a plurality of light-emitting elements are disposed on the transparent layer 100. Since different light-emitting elements typically have different thicknesses, an adhesive layer 300 is disposed between the transparent layer 100 and the light-emitting elements, wherein a material of the adhesive layer 300 may be an elastic material such as silicone. Therefore, the light-emitting elements may partially sink into the adhesive layer 300 to keep electrode surfaces of the light-emitting elements at the same level, and may reduce a height difference of the light-emitting surfaces of each light-emitting element, so that the light emitted from side surfaces of the light-emitting elements may be absorbed as much as possible by a filling layer 600 described below, so as to improve a contrast of the light-emitting device. A thickness of the adhesive layer 300 is preferably 1 μm to 15 μm or 3 μm to 10 μm. If the thickness of the adhesive layer 300 is greater than 15 μm, an alignment accuracy of the light-emitting elements may be affected.

The light-emitting elements in the present embodiment mainly refer to micron-scale light-emitting diodes, whose width or length ranges from 2 μm to 5 μm, 5 μm to 10 μm, 10 μm to 20 μm, 20 μm to 50 μm, or 50 μm to 100 μm, and whose thickness ranges from 2 μm to 15 μm, preferably 5 μm to 10 μm.

Specifically, each light-emitting element includes a semiconductor stacking layer, and the semiconductor stacking layer may include a first semiconductor layer, a second semiconductor layer, and an active layer disposed therebetween arranged in sequence, wherein the first semiconductor layer is an N-type semiconductor layer, the second semiconductor layer is a P-type semiconductor layer, and the active layer is a multi-layer quantum well layer, which may provide radiation of red light or green light or blue light. The N-type semiconductor layer, the multi-layer quantum well layer, and the P-type semiconductor layer are merely the basic constituent units of a light-emitting element 500. On basis of the above, the light-emitting element 500 may further include other functional structural layers that have an optimizing effect on the performance of the light-emitting element 500.

A first light-emitting element 501, a second light-emitting element 502, and a third light-emitting element 503 radiate light rays of different wavelength ranges, respectively. For example, the first light-emitting element 501 radiates blue light rays, the second light-emitting element 502 radiates green light rays, and the third light-emitting element 503 radiates red light rays. In an embodiment, different light-emitting elements 500 may have different semiconductor stacking layers so as to directly radiate light rays of different wavelength ranges, and the specific material of the semiconductor stacking layer is selected according to a wavelength of radiated light rays, which includes but is not limited to aluminum gallium arsenide, gallium arsenide phosphide, aluminum gallium indium phosphide, gallium nitride, indium gallium nitride, zinc selenide, or gallium phosphide. In another embodiment, different light-emitting elements 500 may have the same semiconductor stacking layer. For example, the semiconductor stacking layers in the first light-emitting element 501, the second light-emitting element 502, and the third light-emitting element 503 all radiate blue light rays, and a wavelength conversion layer is disposed on a light-emitting surface of the second light-emitting element 502 to convert the radiated blue light rays into green light rays, and a wavelength conversion layer is disposed on a light-emitting surface of the third light-emitting element 503 to convert the radiated blue light rays into red light rays.

Each light-emitting element 500 further includes a first electrode and a second electrode. The semiconductor stacking layer has a mesa exposing the first semiconductor layer. The first electrode is formed on the mesa and is electrically connected to the first semiconductor layer, and the second electrode is formed on the second semiconductor layer and is electrically connected to the second semiconductor layer.

Referring to FIG. 2a, the filling layer 600 is disposed between adjacent light-emitting elements or around the sidewalls of the light-emitting elements. The disposition of the filling layer 600 may prevent color mixing or light interference between adjacent light-emitting elements, thereby improving the contrast of the light-emitting device. The filling layer 600 is provided as a black adhesive layer that absorbs light. Specifically, the filling layer 600 may be a member formed by dispersing black filling compositions with a particle size of no greater than 1 μm in a transparent or semi-transparent material such as silicone, epoxy resin, polyimide, low-temperature glass, polysiloxane, or polysilazane, and the black filling compositions in the filling layer 600 include but are not limited to carbon black, titanium nitride, iron oxide, triiron tetroxide, iron powder, or the like. The particle size range of the black filling compositions is preferably 10 nm to 100 nm, or 100 nm to 200 nm, or 200 nm to 300 nm, or 300 nm to 500 nm. The filling layer 600 may also employ black dye.

Referring to FIG. 2a, the wiring layer 700 is disposed above the light-emitting elements and the filling layer 600, and is electrically connected to each light-emitting element through metal wirings therein. The wiring layer 700 includes a plurality of wirings, and a periphery of the wiring layer 700 is filled with an insulating layer so as to electrically isolate adjacent wirings from each other. The wiring layer 700 may be a single layer or a multilayer made of at least one material selected from titanium, copper, chromium, nickel, gold, platinum, aluminum, titanium nitride, tantalum nitride, or tantalum. In the present embodiment, the wiring layer 700 includes a two-layer structure, specifically a first layer 701 and a second layer 702, wherein the first layer 701 is in direct contact with the light-emitting elements, and the second layer 702 is formed on the first layer 701. The first layer 701 is provided to adhere the second layer 702 to the light-emitting elements and the filling layer 600, and the second layer 702 mainly functions as a conductor. A material of the first layer 701 includes but is not limited to one or more of titanium, nickel, titanium nitride, tantalum nitride, or tantalum, and a material of the second layer 702 includes but is not limited to one or more of copper, aluminum, or gold. The wiring layer 700 may be prepared by sputtering, evaporation, or the like.

In an embodiment, referring to FIG. 1b, the wiring layer 700 includes a first sub-wiring 710, a second sub-wiring 720, a third sub-wiring 730, and a fourth sub-wiring 740, wherein the first sub-wiring 710 serves as a common wiring. The first electrodes of the first light-emitting element 501, the second light-emitting element 502, and the third light-emitting element 503 are commonly connected to the first sub-wiring 710. A second electrode of the first light-emitting element 501 is connected to the second sub-wiring 720. A second electrode of the second light-emitting element 502 is connected to the third sub-wiring 730. A second electrode of the third light-emitting element 503 is connected to the fourth sub-wiring 740. The wiring layer 300 may be formed on the filling layer 210 as well.

Or, the first sub-wiring 710 serves as a common wiring. The second electrodes of the first light-emitting element 501, the second light-emitting element 502, and the third light-emitting element 503 are commonly connected to the first sub-wiring 710. The first electrode of the first light-emitting element 501 is connected to the second sub-wiring 720. The first electrode of the second light-emitting element 502 is connected to the third sub-wiring 730. The first electrode of the third light-emitting element 503 is connected to the fourth sub-wiring 740. The wiring layer 700 may be formed on the filling layer 600 as well. In an embodiment, referring to FIG. 1b, each sub-wiring includes a first region 700a connected to the light-emitting element, a second region 700b for subsequent bonding to a circuit substrate through a bonding material, and a third region 700c connecting the first region 700a and the second region 700b. The first region 700a and the third region 700b may be linear structures with a width of less than or equal to 50 μm, preferably 5 μm to 20 μm, or 10 μm to 30 μm, or 20 μm to 40 μm. Since the size of the light-emitting device is very small, the space for forming the wiring layer 700 on the light-emitting element is limited; if the width is greater than 50 μm, electrical defect problems are prone to occur; if the width is less than 5 μm, the structures of the first region 700a and the third region 700b are too fragile and are susceptible to the risk of fracture. The shape of the second region 700b may be set to any shape, such as a rectangle, a circle, or other polygons. In the present embodiment, the second region 700b is described as being rectangular or substantially rectangular. The second region 700b is a position for subsequent bonding to the circuit substrate through a bonding material, and if the area is too small, the bonding between the light-emitting device and the substrate will be unstable, and therefore a specific area needs to be maintained.

Referring to FIG. 1a and FIG. 2a, the insulating layer 800 is formed on the wiring layer 700, and the insulating layer 800 may have a portion of the insulating layer 800 removed by exposure and development or the like to form a plurality of opening portions 801 to expose a partial surface of the wiring layer 700, i.e., the second region 700b of the wiring layer 700. In an embodiment, referring to FIG. 2a, the opening portion 801 of the insulating layer 800 includes a lower surface 800a in contact with the wiring layer 700, an upper surface 800b opposite to the lower surface 800a, and a side surface 800c connecting the upper surface 800b and the lower surface 800a, wherein an angle between the side surface 800c and the lower surface 800a is α, and the angle α is less than or equal to 80°. For example, the angle α is less than or equal to 70°, or less than or equal to 60°, or less than or equal to 50°.

In an embodiment, the insulating layer 800 may be formed of materials such as epoxy resin, polysiloxane, or photoresist, which may prevent the wiring layer 700 from being oxidized, and electrically isolate different wirings from each other, thereby avoiding leakage failure in the light-emitting device.

The light-emitting device is subsequently mounted on a circuit substrate using a bonding material such as solder. Specifically, the bonding material may bond the wiring layer 700 exposed at the opening portion 801 of the insulating layer 800 to electrode pads on the circuit substrate. Since the exposed surface of the wiring layer 700 is susceptible to oxidation in air, it may easily lead to electrical defects and other problems. Therefore, in an embodiment, referring to FIG. 1a and FIG. 2a, a protective electrode 900 is formed on a surface of the wiring layer exposed within the opening portion 801 of the insulating layer 800, i.e., in the second region 700b, so that when the material forming the wiring layer 700 is susceptible to oxidation, for example, in an embodiment, when a surface metal of the wiring layer 700 is Cu, forming the protective electrode 900 may protect the exposed wiring layer 700. A plurality of the protective electrodes 900 are formed in the second region 700b of the exposed wiring layer 700 and are electrically connected to the wiring layer 700. A shape of the protective electrode 900 may be set to any shape, such as a rectangle, a circle, or other polygons. In the present embodiment, the protective electrode 900 is described as being rectangular or substantially rectangular. Referring to FIG. 1a, each of the protective electrodes 900 includes four sidewalls, which are a first sidewall 901, a second sidewall 902, a third sidewall 903, and a fourth sidewall 904, respectively. The first sidewall 901 and the second sidewall 902 of each of the protective electrodes 900 are away from an edge of the light-emitting device and are disposed close to the center of the light-emitting device. Moreover, in the present embodiment, a total of four protective electrodes 900 are provided.

In an embodiment, referring to FIG. 1a, the light-emitting device includes a first side 001, a second side 002, a third side 003, and a fourth side 004 connected in sequence, wherein the first side 001 and the third side 003 are substantially parallel with each other, and the second side 002 and the fourth side 004 are substantially parallel with each other, or it may be said that the first side 001 and the third side 003 are parallel with each other, and the second side 002 and the third side 004 are parallel with each other. The first side 001 is substantially parallel to the first sidewall 901, the second side 002 is substantially parallel to the second sidewall 902, the third side 003 is substantially parallel to the third sidewall 903, and the fourth side 004 is substantially parallel to the fourth sidewall 904.

In an embodiment, referring to FIG. 1a, a length of the first side 001 is equal to a length of the second side 002 (due to measurement errors, an error range within 10% is permissible), and a length of the first sidewall 901 of the protective electrode 900 is equal to a length of the second sidewall 902 (due to measurement errors, an error range within 10% is permissible).

In another embodiment, the length of the first side 001 is less than the length of the second side 002, and the plurality of light-emitting elements are arranged in a direction of the second side 002. A ratio of the length of the first side 001 to the length of the second side 002 is greater than a ratio of the length of the first sidewall 901 to the length of the second sidewall 902 of the protective electrode 900. In a preferred embodiment, when the ratio of the length of the first side 001 to the length of the second side 002 is between 0.6 and 0.9, the ratio of the length of the first sidewall 901 to the length of the second sidewall 902 of the protective electrode 900 is between 0.4 and 0.8, which may ensure that the protective electrode retains a sufficient area to bond with the display panel when the size of the light-emitting device is further reduced.

In an embodiment, referring to FIG. 2b, the protective electrode 900 includes a first portion 900a formed in the second region 700b of the wiring layer 700 and a second portion 900b formed on the side surface 800c of the opening portion 801 of the insulating layer 800, wherein the first portion 900a and the second portion 900b may be in contact with each other in continuation, which may provide effective anti-oxidation protection for the exposed surface of the wiring layer 700 to form a good contact with a solder paste during subsequent soldering. A thickness of the first portion 900a is greater than a thickness of the second portion 900b, and the thickness of the second portion 900b gradually decreases with an increasing distance from the first portion 900a, so that an edge of the protective electrode 900 has a good adhesion to the side surface 800c of the opening portion 801 of the insulating layer 800.

In an embodiment, a material of the protective electrode 900 may be one or more of metals such as nickel, gold, or platinum, and may also be chromium, tin, or palladium. A thickness of the protective electrode 900 is between 1 μm and 6 μm, for example, the thickness of the protective electrode 900 may be 2 μm, 3 μm, 4 μm, or 5 μm.

In an embodiment, the protective electrode 900 includes a first-layer structure and a second-layer structure, wherein a thickness of the first-layer structure is greater than a thickness of the second-layer structure. In a preferred embodiment, the first-layer structure may be a nickel layer, and the second-layer structure may be a gold layer, the thickness of the first-layer structure is 2 μm to 5 μm, and the thickness of the second-layer structure is 20 Å to 50 Å, and the setting of a thickness ratio may achieve a better planarity. In an embodiment, the wiring layer 700 includes copper metal, for example, when the surface metal is copper, a portion of the copper metal is in contact with the insulating layer 800, and a portion of the copper metal is exposed by the opening portion 801 of the insulating layer, thereby being in contact with the protective electrode 900 and being protected by the protective electrode 900 to prevent oxidation thereof.

In an embodiment, the thickness of the protective electrode 900 is greater than a thickness of the wiring layer 700, and the thickness of the protective electrode 900 is less than a thickness of the insulating layer 800. In an embodiment, the thickness of the insulating layer 800 is between 2 μm and 10 μm, for example, the thickness of the insulating layer 800 may be 4 μm, 5 μm, 6 μm, or 7 μm, and setting the insulating layer 800 to be thicker within the above range is beneficial to enhancing a mechanical strength of the product, but if the insulating layer 800 is too thick and exceeds the above range, it may lead to poor electrical property.

In an embodiment, referring to FIG. 2a, the thickness of the protective electrode 900 is less than the thickness of the insulating layer 800, and there is a minimum distance D1 between a surface of the protective electrode 900 and the upper surface 800b of the insulating layer 800, the thickness of the insulating layer 800 is H1, and a height difference between the D1 and H1 is between 0 μm and 10 μm. Where D1 is excessively large, the subsequent mounting of the light-emitting device on the circuit substrate may require the use of a greater volume of solder or other bonding materials. As D1 increases, a heating time required for such bonding materials correspondingly increases, which may adversely affect the performance of the light-emitting device.

FIG. 2c is a schematic cross-sectional view taken along line A-A′ of FIG. 1a of another embodiment in Embodiment 1 of the present disclosure. In an embodiment, referring to FIG. 1a and FIG. 2c, the protective electrode 900 is formed in the second region 700b of the wiring layer 700, and the insulating layer 800 covers the partial surface of the wiring layer 700 and a sidewall and a partial surface of the protective electrode 900. Specifically, the insulating layer 800 is formed on the wiring layer 700, and the opening portion 801 is formed to expose the surface of the protective electrode 900, and a projection of the opening portion 801 has an overlapping area with the protective electrode 900. In a preferred embodiment, the projection of the opening portion 801 is located within a projection of the protective electrode 900. The edge and the sidewall of the protective electrode 900 are covered by the insulating layer 800, which may prevent external moisture from entering the interior of the light-emitting device, thereby improving the reliability of the light-emitting device. In addition, in the present embodiment, the protective electrode 900 may first be formed in the second region 700b of the wiring layer 700 through a wet process, and then the insulating layer 800 covers the surface of the wiring layer 700 and the sidewall and the partial surface of the protective electrode 900, which may prevent cracks from forming between the sidewall 800c of the opening portion 801 of the insulating layer 800 and the surface of the wiring layer 700, thereby improving the reliability of the light-emitting device.

In an embodiment, the wiring layer 700 includes copper metal, for example, when the surface metal is copper, a portion of the copper metal is in contact with the insulating layer 800, and the protective electrode 900 includes gold metal, and a surface of a portion of the gold metal is covered by the insulating layer 800 so as to be in contact therewith, which may prevent cracks from forming between the sidewall 800c of the opening portion 801 of the insulating layer 800 and the surface of the wiring layer 700, thereby improving the reliability of the light-emitting device.

In an embodiment, there is a distance between an edge of the insulating layer 800 covering the partial surface of the protective electrode 900 and the edge of the protective electrode 900, and the distance is between 0 μm and 10 μm. If the distance is less than 0 μm, the insulating layer 800 may not be able to completely cover the exposed surface of the wiring layer 700, thereby causing oxidation thereof; if the distance is greater than 10 μm, it may reduce an area of contact between the protective electrode 900 and the bonding material, affecting its contact with the circuit substrate.

In an embodiment, the sidewall of the protective electrode 900 is an uneven structure.

### Embodiment 2

This embodiment provides a light-emitting device. The similarities between the light-emitting device and the light-emitting device in Embodiment 1 will not be repeated here, and the differences are as follows:

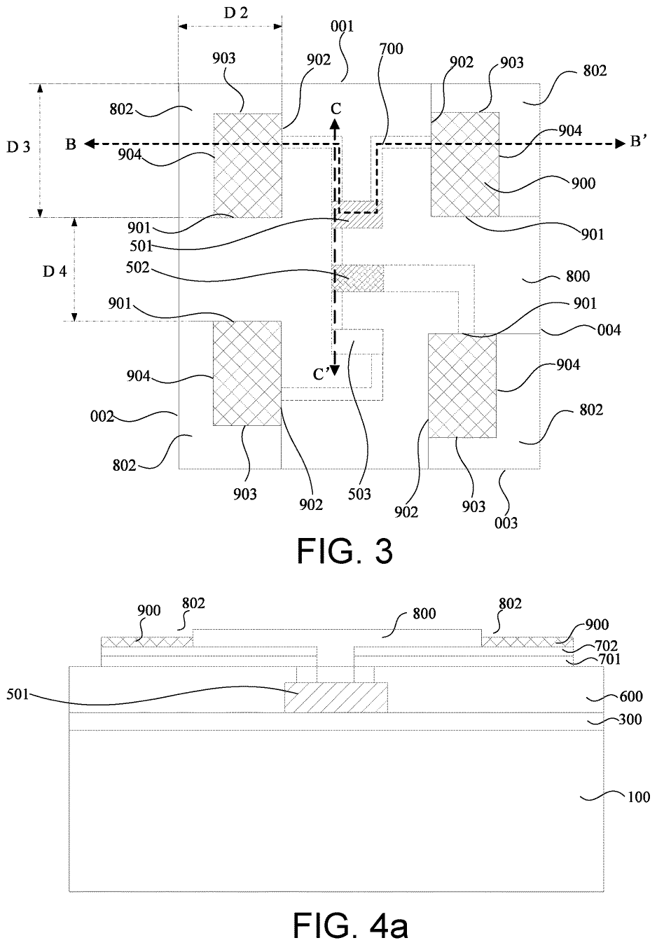

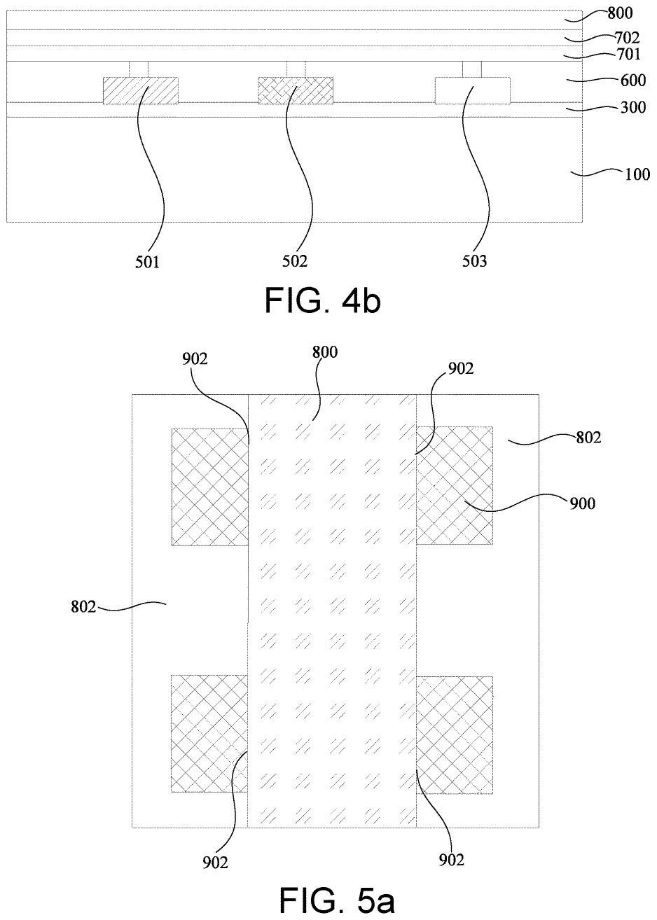

FIG. 3 is a structural top view of a specific embodiment in the present embodiment; FIG. 4a is a schematic cross-sectional view taken along line B-B′ of FIG. 3; FIG. 4b is a schematic cross-sectional view taken along line C-C′ of FIG. 3.

Referring to FIG. 3 to FIG. 4b, in this embodiment, a plurality of notch portions 802 spaced apart are formed at the edge of the insulating layer 800. Optionally, the wiring layer 700 (i.e., the second region 700b) may be exposed within each of the notch portions 802, or the protective electrode 900 formed in the second region 700b of the wiring layer 700 may be exposed. Since the thickness of the protective electrode 900 in Embodiment 1 is less than the thickness of the insulating layer 800, a recess is formed on a surface of the insulating layer 800 at the opening portion 801. Meanwhile, since the size of the light-emitting element in this embodiment is smaller, the size of the package is also smaller, resulting in a smaller size of the protective electrode 900 exposed on the surface of the insulating layer 800, and correspondingly, the size of the recess formed on the insulating layer 800 is also smaller. When a blue film is provided to transfer the entire light-emitting device, the blue film is attached to a side of the light-emitting device having the insulating layer 800 with the recess. Due to the presence of small recesses on the surface of the insulating layer 800, and because the size of the recesses is small, a large negative pressure is easily generated during a demolding process, resulting in the inability to efficiently demold the light-emitting device and affecting the transfer efficiency. Therefore, in this embodiment, the plurality of notch portions 802 are formed at the edge of the insulating layer 800, the notch portions 802 expose at least a partial edge of the light-emitting device, and since the protective electrode 900 is exposed within the notch portions 802 located at the edge of the insulating layer 800, no recess is formed on the surface of the insulating layer 800. When transferring the entire light-emitting device, no negative pressure is generated between the light-emitting device and the blue film, and thus the light-emitting device of this embodiment may improve the transfer efficiency and device yield.

Referring to FIG. 3, there is a minimum distance D2 between an edge of the notch portion 802 of the insulating layer 800 and the edge of the light-emitting device, and the minimum distance D2 is less than 120 μm. Optionally, the minimum distance may be set within 20 μm to 80 μm, so that the insulating layer may completely cover the wiring layer or wiring on the light-emitting device.

In an embodiment, referring to FIG. 3, each of the notch portions 802 includes a first edge and a second edge. The first edge of the notch portion 802 is arranged substantially parallel to the second side 002, the second edge of the notch portion 802 is arranged substantially parallel to the first side 001, a ratio of the minimum distance D2 from the first edge to the second side 002 to the first side 001 is 0.1 to 0.5, and a ratio of a minimum distance D3 from the second edge to the first side 001 to the length of the second side 002 is 0.3 to 0.6.

In an embodiment, referring to FIG. 3, the light-emitting device includes the first side 001, the second side 002, the third side 003, and the fourth side 004. The first side 001 and the third side 003 are arranged opposite to each other, and the second side 002 and the fourth side 004 are arranged opposite to each other. The length of the second side 002 is greater than the length of the first side 001. Along an extending direction of the second side 002, a distance D4 between two of the adjacent protective electrodes 900 is greater than 40 μm. Optionally, a ratio of the distance D4 between the two adjacent protective electrodes 900 to the length of the second side 002 is 1:4, and a ratio of the distance D4 between the two adjacent protective electrodes to the length of the first side 001 is 1:2. Optionally, along the extending direction of the second side 002, the distance D4 between the two adjacent protective electrodes is 40 μm to 100 μm.

In an embodiment, referring to FIG. 3 to FIG. 4b, a plurality of light-emitting elements are spaced apart on the transparent layer 100, and a ratio of a projection area of the insulating layer 800 on the transparent layer 100 to an area of the transparent layer 100 is 0.4 to 0.8. Optionally, a ratio of a projection area of the notch portions 802 of the plurality of insulating layers 800 on the transparent layer 100 to the area of the transparent layer 100 is 0.2 to 0.6.

Referring to FIG. 3 to FIG. 4b, in this embodiment, the size of each of the protective electrodes 900 is smaller than a size of each of the notch portions 802. Each of the protective electrodes 900 is exposed within each of the notch portions 802, and the edge of the protective electrode 900 has a spacing from the edge of the light-emitting device, which may prevent the protective electrode 900 from being formed at an edge of the wiring layer 700. In this embodiment, arranging the protective electrode 900 at a position close to the center of the light-emitting device may prevent the exposure of the protective electrode 900 and prevent leakage or damage to the protective electrode 900. Optionally, a material of the protective electrode 900 is tin, gold, or a tin-gold alloy. An area of the protective electrode 900 exposed within the notch portion 802 of the insulating layer 800 is much smaller than an area of the wiring layer 700. Exposing the protective electrode 900 only within the notch portion 802 or the opening portion 801, rather than directly plating tin or gold material on the entire wiring layer 700, may save the amount of tin and gold material used and reduce production costs.

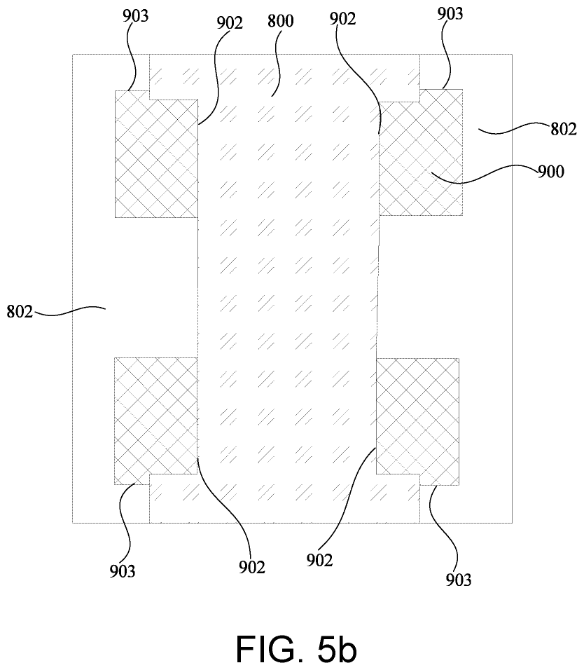

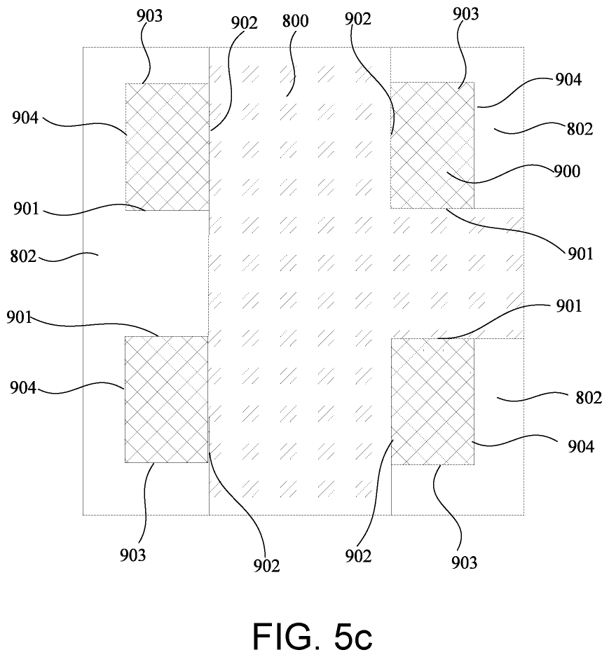

In a specific embodiment of this embodiment, referring to FIG. 5a to FIG. 5b, the insulating layer 800 includes two notch portions 802 spaced apart from each another. Each of the notch portions 802 has two protective electrodes 900 exposed therein, and the two protective electrodes 900 are spaced apart within the notch portion 802. For example, the insulating layer 800 completely covers the second sidewall 902 of the protective electrode 900, so that the insulating layer 800 is in a “|” shape, as shown in FIG. 5a. The insulating layer 800 completely covers the second sidewall 902 and partially covers the third sidewall 903 adjacent to the second sidewall 902, so that the insulating layer 800 is in an “I” shape, as shown in FIG. 5b. Furthermore, the insulating layer 800 may not only cover the sidewall of the protective electrode 900, but also cover the partial surface of the protective electrode 900, as shown in FIG. 5b. In the above embodiments, the length of the first sidewall 901 of the protective electrode 900 is greater than the length of the second sidewall 902.

In a specific embodiment, referring to FIG. 5c, the insulating layer 800 includes three notch portions 802 spaced apart from one another, the insulating layer 800 completely covers the second sidewall 902 of each of the protective electrodes 900, and covers the first sidewall 901 of the two adjacent protective electrodes 900 arranged opposite to each other to completely cover the wiring layer at the bottom.

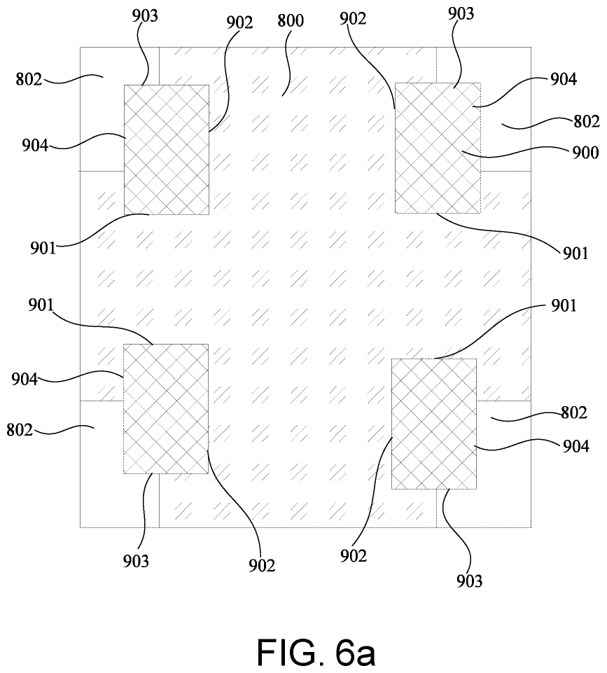

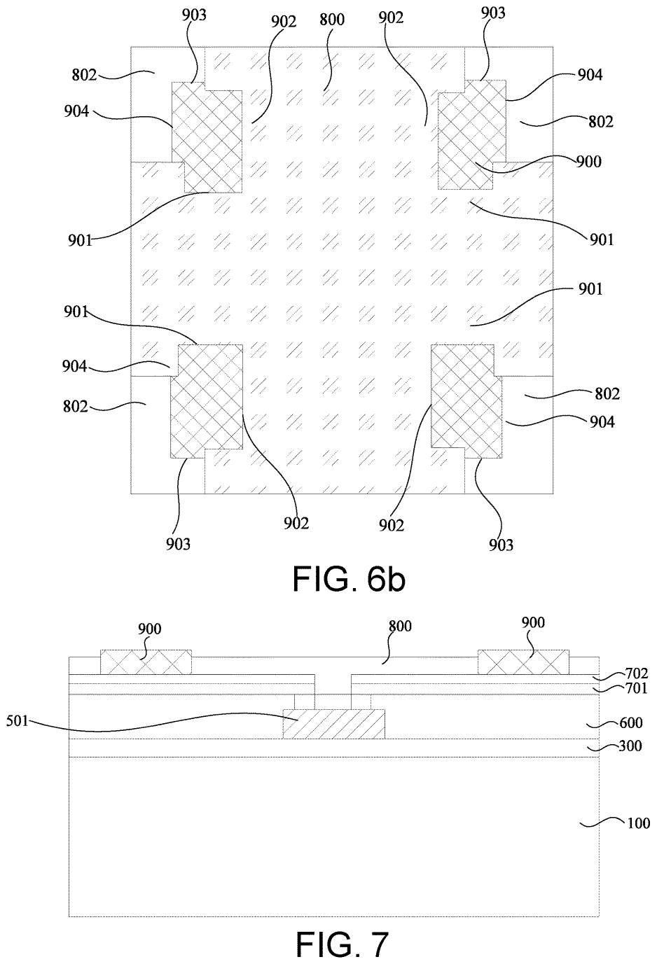

In a specific embodiment of this embodiment, referring to FIG. 3, FIG. 6a to FIG. 6b, the insulating layer 800 includes four notch portions 802 spaced apart from one another. Each of the notch portions 802 has one protective electrode 900 exposed therein. For example, the insulating layer 800 completely covers the first sidewall 901 and the second sidewall 902 of each of the protective electrodes 900, so that the insulating layer 800 is in a “+” shape, as shown in FIG. 3. The insulating layer 800 completely covers the first sidewall 901 and the second sidewall 902 of each of the protective electrodes 900, and extends from the first sidewall 901 to the fourth sidewall 904, and extends from the second sidewall 902 to the third sidewall 903, as shown in FIG. 6a or FIG. 6b. Meanwhile, as shown in FIG. 6b, the insulating layer 800 not only covers the sidewall of the protective electrode 900, but also covers the partial surface of the protective electrode 900.

It should be noted that the insulating layer 800 in this embodiment may be in any shape, as long as no recess is formed on the surface of the insulating layer 800, it is possible to resolve the problem of negative pressure generated between the blue film and the light-emitting device. Meanwhile, the protective electrode 900 may also be configured to resolve the above-mentioned problems in this embodiment. For example, as shown in FIG. 7, setting the thickness of the protective electrode 900 to be greater than or equal to the thickness of the insulating layer 800 may also prevent recess from forming on the surface of the insulating layer 800, thereby avoiding the problem of negative pressure being generated between the blue film and the light-emitting device.

### Embodiment 3

The similarities between this embodiment and the light-emitting device described in FIG. 1a and FIG. 2a or FIG. 3 and FIG. 4a to FIG. 4b in Embodiment 1 will not be repeated here, and the differences are as follows:

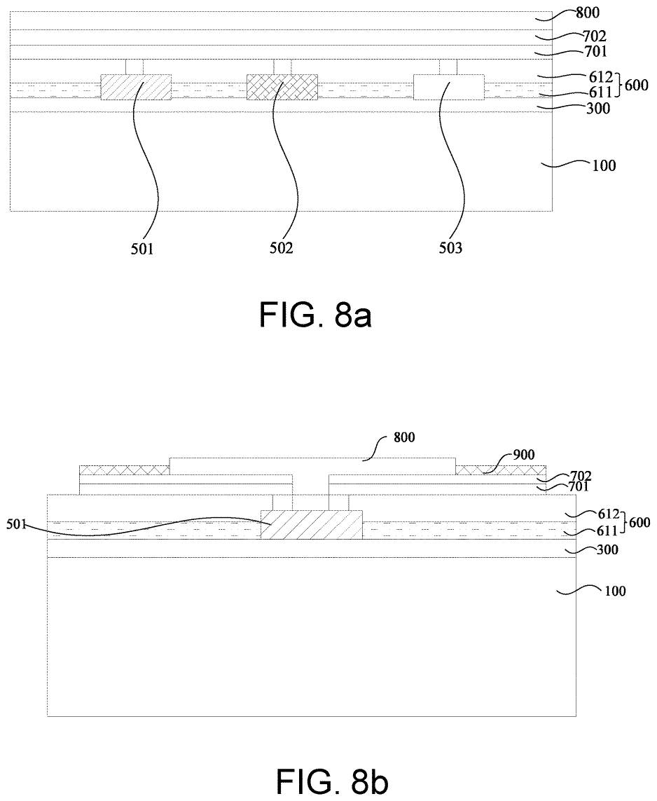

FIG. 8a is a schematic cross-sectional view taken along line C-C′ in FIG. 3 in a specific embodiment of this embodiment; FIG. 8b is a schematic cross-sectional view taken along line B-B′ in FIG. 3 in a specific embodiment of this embodiment. Referring to FIG. 8a or referring to FIG. 8b, in this embodiment, the filling layer 600 formed between adjacent light-emitting elements includes a first filling structure. The filling structure is at least arranged at the sidewall of each light-emitting element, and the first filling structure includes a first sub-layer 611 and a second sub-layer 612 formed on the first sub-layer 611, and a thickness of the first sub-layer 611 is less than a thickness of the second sub-layer 612. The first sub-layer 611 may absorb light emitted from adjacent light-emitting elements, preventing optical crosstalk between adjacent light-emitting elements, while forming a better contrast with the second sub-layer 612. The second sub-layer 612 may reflect light at the sidewall of the light-emitting element toward a light-emitting direction, and may also prevent optical crosstalk between adjacent light-emitting elements. Meanwhile, due to the presence of the second sub-layer 612, the contrast of the light-emitting device may also be improved, which is beneficial to the enhancement of the display effect. The filling layer 600 in Embodiment 1 is formed as an entire black light-absorbing layer, and using only the black light-absorbing layer to absorb the light emitted from a side surface of a chip increases the light loss of the chip itself. Therefore, compared with the filling layer 600 arrangement in Embodiment 1, a light output of this embodiment is increased and the display effect is better.

Optionally, the first sub-layer 611 in this embodiment is a black material layer, and the black material layer contains black filling compositions, and the black filling compositions include at least one of carbon black, titanium nitride, iron oxide, triiron tetroxide, or iron powder. The second sub-layer 612 is a white reflective material layer or a DBR reflective layer, and may specifically be a white reflective material layer, so that the white reflective material layer may form a relatively high contrast with the black material layer of the first sub-layer 611. Optionally, the white reflective material layer may be a foamed material of polyethylene terephthalate, a high-reflectance white polypropylene, a white polycarbonate (PC) resin, or the like.

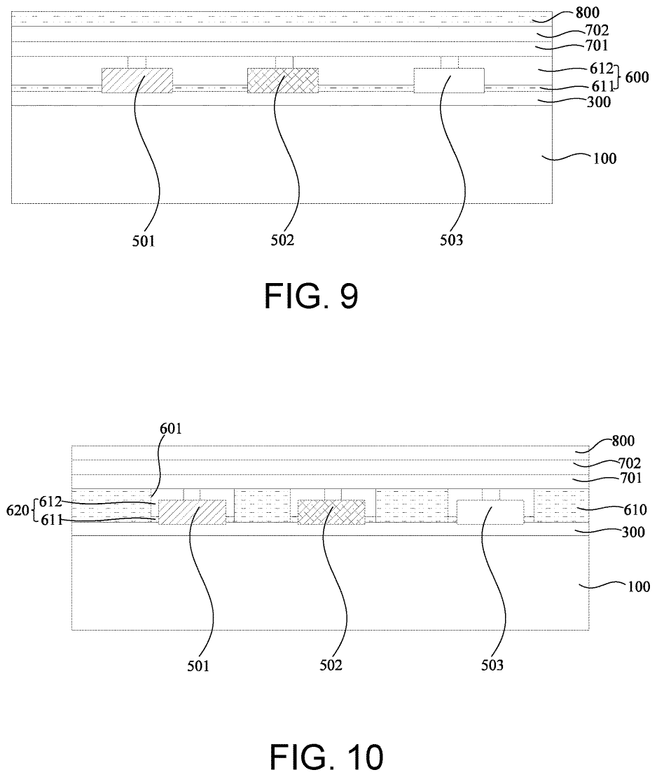

Specifically, referring to FIG. 8a, FIG. 8b, or FIG. 9, the filling layer 600 as a whole may be formed as a first filling structure 610, and the first filling structure 610 includes the first sub-layer 611 and the second sub-layer 612.

In a specific embodiment of this embodiment, as shown in FIG. 8a and FIG. 8b, the filling layer 600 as a whole is formed as the first filling structure 610. Moreover, along a direction from the light-emitting element to the wiring layer 700, the first filling structure 610 includes the first sub-layer 611 and the second sub-layer 612 in sequence along the sidewall of the light-emitting element, and a ratio of a thickness of the first sub-layer 611 to a thickness of the second sub-layer 612 is 0.2 to 1. Optionally, the ratio of the thickness of the first sub-layer 611 to the thickness of the second sub-layer 612 is 0.4 to 0.8. For example, the ratio of the thickness of the first sub-layer 611 to the thickness of the second sub-layer 612 is 5:8, and this ratio setting of the first sub-layer 611 and the second sub-layer 612 may effectively improve the brightness of the light-emitting element. In testing of the brightness of the light-emitting device obtained from FIG. 1 and FIG. 2 in Embodiment 1 and the light-emitting device obtained in this embodiment, the brightness of the red light-emitting element, the green light-emitting element, and the blue light-emitting element in the light-emitting device obtained from FIG. 1 and FIG. 2 in Embodiment 1 may all reach 100%. In the light-emitting device obtained in this embodiment, the brightness of the red light-emitting element may be increased to 101%, the brightness of the green light-emitting element may be increased to 102.5%, and the brightness of the blue light-emitting element may be increased to 103%. In another specific embodiment of this embodiment, as shown in FIG. 9, the filling layer 600 as a whole is formed as the first filling structure 610. Along a direction from the light-emitting element to the wiring layer 700, the filling structure includes the first sub-layer 611 and the second sub-layer 612 in sequence along the sidewall of the light-emitting element, and the ratio of the thickness of the first sub-layer 611 to the thickness of the second sub-layer 612 is 0.2 to 1. In the meantime, in order to avoid crosstalk caused by lateral emission from the back side of the light-emitting device, the insulating layer 800 in this embodiment is also configured as a black material layer, and the black material layer contains black filling compositions, and the black filling compositions include at least one of carbon black, titanium nitride, iron oxide, triiron tetroxide, or iron powder. Furthermore, the insulating layer 800 may prevent crosstalk caused by lateral emission from the back side. Optionally, a material layer is also formed between the two electrodes of each light-emitting element, and the material layer is not implemented based on the same process as the insulating layer 800, and the material layer may be a black material layer or a white reflective material layer. For example, when the material layer is a white material layer, it may reflect light incident on the back side, thereby increasing the brightness of the light-emitting device.

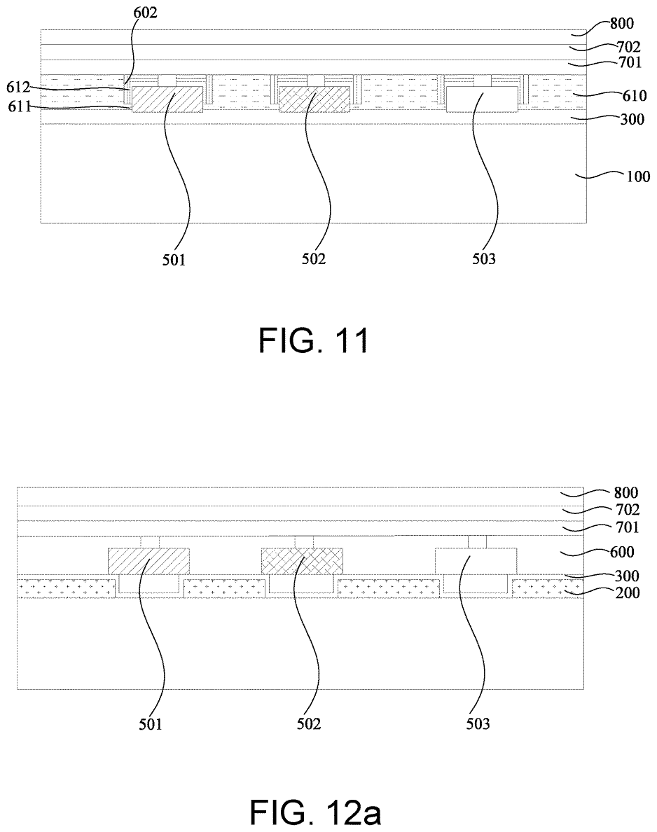

Referring to FIG. 10 or FIG. 11, the filling layer 600 may also include the first filling structure 610 and the second filling structure 620. In a specific embodiment of this embodiment, as shown in FIG. 10, the filling layer 600 includes the first filling structure 610 and the second filling structure 620, a gap 601 exists between the second filling structure 620 and the sidewall of the light-emitting element, and the first filling structure 610 is filled within the gap 601. Along A direction from the light-emitting element to the wiring layer 700, the filling structure includes the first sub-layer 611 and the second sub-layer 612 in sequence along the sidewall of the light-emitting element, and the ratio of the thickness of the first sub-layer 611 to the thickness of the second sub-layer 612 is 0.2 to 1. In a specific embodiment of this embodiment, as shown in FIG. 11, the filling layer 600 includes the first filling structure 610 and the second filling structure 620, a groove 203 is formed on a surface of the second filling structure 620 close to the wiring layer 700, a bottom wall of the groove 203 is formed as the first sub-layer 611, and the second sub-layer 612 is formed within the groove 203. Furthermore, the second sub-layer 612 is formed as a DBR reflective layer. Along the direction from the light-emitting element to the wiring layer 700, the filling structure includes the first sub-layer 611 and the second sub-layer 612 in sequence along the sidewall of the light-emitting element, and the ratio of the thickness of the first sub-layer 611 to the thickness of the second sub-layer 612 is 0.2 to 1.

Optionally, the adhesive layer 300 provided to bond the transparent layer 100 and the plurality of light-emitting elements may be replaced with a high-reflectance index material, so as to avoid the reduction of light output at an interface between the light-emitting element and the adhesive layer 300, thereby further increasing the brightness of the light-emitting device. For example, the material of the adhesive layer 300 may be epoxy resin.

### Embodiment 4

The similarities between this embodiment and the light-emitting device described in FIG. 1a and FIG. 2a or FIG. 3 and FIG. 4a to FIG. 4b in Embodiment 1 will not be repeated here, and the differences are as follows:

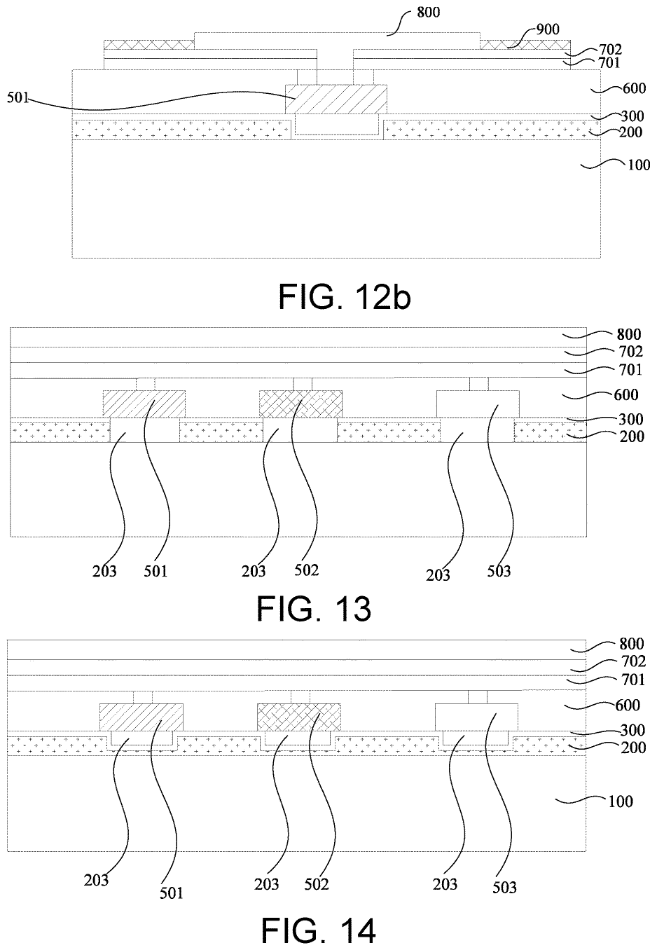

FIG. 12a is a schematic cross-sectional view taken along line C-C′ in FIG. 3 of a specific embodiment of this embodiment, and FIG. 12b is a schematic cross-sectional view taken along line B-B′ in FIG. 3 of a specific embodiment of this embodiment.

Referring to FIG. 12a or FIG. 12b, this embodiment provides an overhead layer 200 between the transparent layer 100 and the adhesive layer 300, and the overhead layer 200 is formed on the surface of the transparent layer 100. The overhead layer 200 includes a first surface 201 and a second surface 202 disposed opposite to each other. The first surface 201 is in contact with the transparent layer 100, and at least one groove 602 is formed on the second surface 202, and the groove 602 is recessed in a direction from the second surface 202 to the first surface 201. The adhesive layer 300 is formed at least on the second surface 202 of the overhead layer 200. A plurality of light-emitting elements are spaced apart on the adhesive layer 300, at least one light-emitting element corresponds to one groove 602, and a partial surface of the light-emitting element is in contact with the adhesive layer 300. When the luminous intensity of the light-emitting element is high or undergoes an abrupt change, the adhesive layer 300 located on a light-emitting side of the light-emitting element may also age in a high-temperature or high-humidity environment, causing the thickness of the adhesive layer 300 to become thinner or causing bubbles to generate within the layer. Also, the change in the structure of the adhesive layer 300 may also affect the light emitted from the light-emitting element to the transparent layer 100, and may even change the luminous intensity of the light-emitting element, causing the product to exhibit unstable reliability, especially for blue light-emitting elements, where this phenomenon is particularly significant. This embodiment provides the overhead layer 200 between the transparent layer 100 and the adhesive layer 300, and separates the adhesive layer 300 from the light-emitting region of the light-emitting element through the groove 602 provided on the overhead layer 200, so as to avoid the light output of the light-emitting element from affecting the properties of the adhesive layer 300, which would ultimately affect the light output intensity of the entire device, thereby improving the reliability of the device.

Specifically, referring to FIG. 12a, FIG. 12b, or FIG. 13, the groove 602 formed on the overhead layer 200 may also completely penetrate through the overhead layer 200 to expose the surface of the transparent layer 100. In this case, the overhead layer 200 may be a light-transmitting layer or a photoresist layer. Optionally, the photoresist layer contains black filling compositions, and the black filling compositions include at least one of carbon black, titanium nitride, iron oxide, triiron tetroxide, or iron powder. Optionally, the light-transmitting layer may be transparent silicon dioxide, transparent polyimide, or the like. Referring to FIG. 14, the groove 602 formed on the overhead layer 200 may partially penetrate through the overhead layer 200, so that a depth of the groove 602 is less than a thickness of the overhead layer 200. In this case, the overhead layer 200 is formed as a whole as a light-transmitting layer, so as to avoid blocking the light output of the light-emitting element.

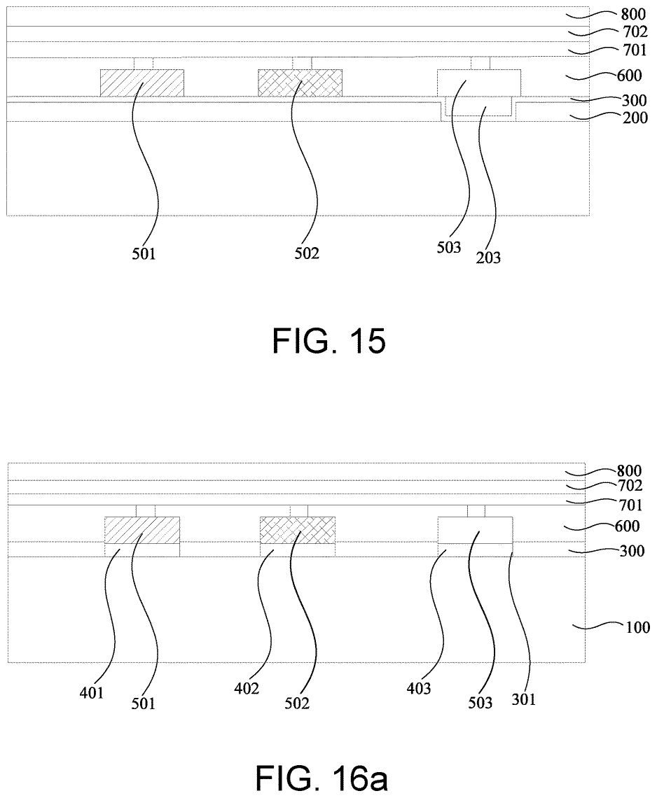

Referring to FIG. 12a, FIG. 12b, or FIG. 13, the adhesive layer 300 is formed at least on the second surface 202. Optionally, referring to FIG. 13, the adhesive layer 300 may be formed only on the second surface 202; referring to FIG. 12a, FIG. 12b, FIG. 14, or FIG. 15, the adhesive layer 300 may also be formed on both the second surface 202 and an inner wall of the groove 602 at the same time. When the adhesive layer 300 is formed on the inner wall of the groove 602, it is necessary to control a distance between the adhesive layer 300 located on a bottom wall of the groove 602 and the light-emitting element overhead above the groove 602, so as to ensure that when an abrupt change occurs in the luminous intensity of the light-emitting element, the luminous intensity affects the structure of the adhesive layer 300. In this embodiment, as shown in FIG. 12a, FIG. 12b, FIG. 14, or FIG. 15, a vertical distance between the adhesive layer 300 located on the bottom wall of the groove 602 and the light-emitting region of the corresponding light-emitting element is between 5 μm and 17 μm, and the thickness of the overhead layer 200 and the depth of the groove 602 may be adjusted according to the vertical distance between the adhesive layer 300 and the light-emitting region of the corresponding light-emitting element, which will not be described in further detail here.

Referring to FIG. 12a to FIG. 15, a plurality of light-emitting elements are spaced apart from one another on the adhesive layer 300, the light-emitting region of at least one light-emitting element corresponds to one groove 602, and an edge of the light-emitting element is in contact with the adhesive layer 300 formed on the second surface 202 of the overhead layer 200, so that the light-emitting region of the light-emitting element is overhead above the groove 602. Optionally, the plurality of light-emitting elements may include at least three light-emitting elements that emit light of different colors from each other, wherein one of the light-emitting elements is a light-emitting element that emits blue light. In this case, it may be that only one groove 602 is formed on the overhead layer 200, and the light-emitting region of the light-emitting element that emits blue light corresponds to the groove 602. Optionally, the plurality of light-emitting elements includes three light-emitting elements, and each light-emitting element is a light-emitting element that emits blue light. In this case, three grooves 602 are provided on the overhead layer 200, and each groove 602 corresponds to one light-emitting element. Optionally, when the plurality of light-emitting elements are respectively a light-emitting element that emits red light, a light-emitting element that emits blue light, and a light-emitting element that emits blue light, three grooves 602 may also be provided on the overhead layer 200, and each groove 602 corresponds to one light-emitting element.

In a specific embodiment of this embodiment, as shown in FIG. 12a, three grooves 602 are provided on the second surface 202 of the overhead layer 200, and the grooves 602 completely penetrate through the overhead layer 200, so that the bottom of the grooves 602 exposes the transparent layer 100. The adhesive layer 300 is formed on the second surface 202 of the overhead layer 200 and the inner wall of the grooves 602. Moreover, the light-emitting device in this embodiment includes three light-emitting elements, which are respectively a first light-emitting element 501, a second light-emitting element 502, and a third light-emitting element 503.

The first light-emitting element 501 is a red light-emitting element, the second light-emitting element 502 is a green light-emitting element, and the third light-emitting element 503 is a blue light-emitting element, and the light-emitting region of each light-emitting element corresponds to one groove 602 and is disposed overhead. The overhead layer 200 is formed as a photoresist layer to prevent optical crosstalk between adjacent light-emitting elements.

In a specific embodiment of this embodiment, as shown in FIG. 13, the adhesive layer 300 is formed only on the second surface 202 of the overhead layer 200. Moreover, the groove 602 completely penetrates through the overhead layer 200, so that the bottom of the groove 602 exposes the transparent layer 100.

In a specific embodiment of this embodiment, as shown in FIG. 14, the groove 602 penetrates through a portion of the overhead layer 200, and the depth of the groove 602 is less than the thickness of the overhead layer 200. In this case, the overhead layer 200 is a light-transmitting layer, so that light may pass through the overhead layer 200 through the bottom wall of the groove 602, and the material of the light-transmitting layer is transparent polyimide.

In a specific embodiment of this embodiment, as shown in FIG. 15, one groove 602 is provided on the second surface 202 of the overhead layer 200, and the groove 602 penetrates through the overhead layer 200, so that the bottom of the groove 602 exposes the surface of the transparent layer 100. In this case, the overhead layer 200 is formed as a photoresist layer to prevent optical crosstalk between adjacent light-emitting elements. The adhesive layer 300 is formed on the second surface 202 and the inner wall of the groove 602. The light-emitting device in this embodiment includes three light-emitting elements, which are respectively the first light-emitting element 501, the second light-emitting element 502, and the third light-emitting element 503. The first light-emitting element 501 is a red light-emitting element, the second light-emitting element 502 is a green light-emitting element, and the third light-emitting element 503 is a blue light-emitting element, and the light-emitting region of the blue light-emitting element is disposed corresponding to the groove 602 on the overhead layer 200.

### Embodiment 5

The similarities between this embodiment and the light-emitting device described in FIG. 1 and FIG. 2a or FIG. 3 and FIG. 4 in Embodiment 1 will not be repeated here, and the differences are as follows:

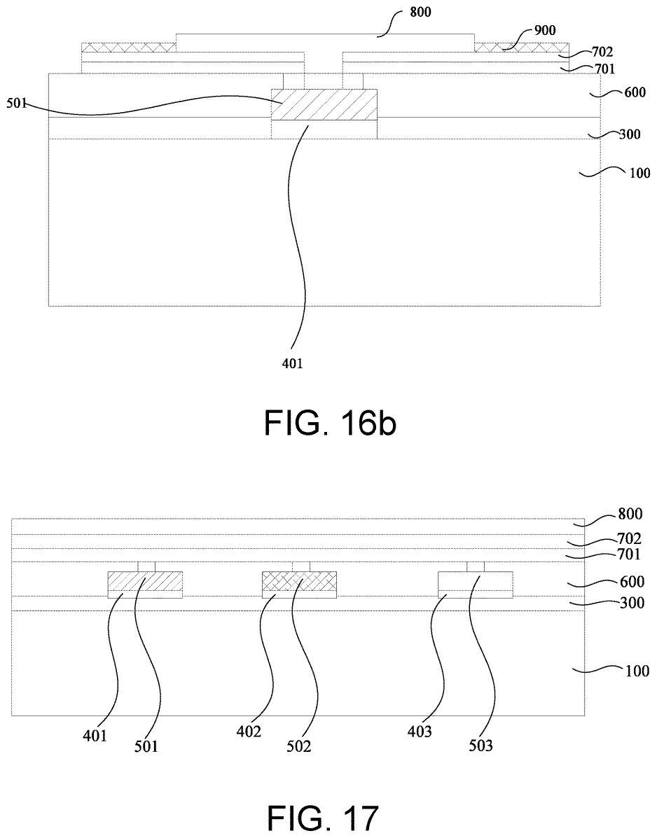

Referring to FIG. 16a to FIG. 19, the light-emitting device in this embodiment further includes a plurality of angle adjustment layers 400 disposed between the transparent layer 100 and the plurality of light-emitting elements, and the angle adjustment layers 400 correspond to the light-emitting elements one by one. The angle adjustment layer 400 may adjust the light-emitting angle of each light-emitting element to expand the light-emitting angle of each light-emitting element, so as to avoid blind zones between adjacent light-emitting elements that may affect the display effect. Optionally, the angle adjustment layer 400 may be a DBR reflective layer, and the DBR reflective layer has a reflectance of more than 80% for light with an incident angle of 0 to 20 degrees, a reflectance of 45% to 60% for light with an incident angle of 20 to 35 degrees, and a reflectance of 40% or less for light with an incident angle of 35 to 90 degrees.

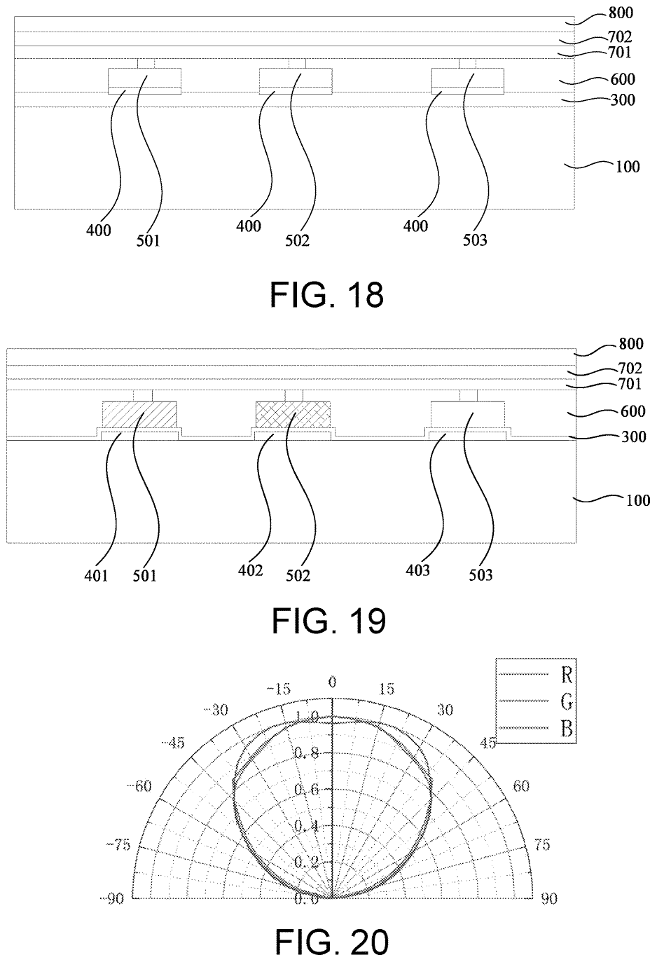

Specifically, referring to FIG. 16a or FIG. 17, three light-emitting elements may be provided. When the three light-emitting elements are respectively a red light-emitting element, a green light-emitting element, and a blue light-emitting element, the angle adjustment layer 400 corresponding to each light-emitting element varies. In this case, the angle adjustment layer 400 includes a first angle adjustment layer 401, a second angle adjustment layer 402, and a third angle adjustment layer 403, wherein the first angle adjustment layer 401 corresponds to the red light-emitting element, the second angle adjustment layer 402 corresponds to the green light-emitting element, and the third angle adjustment layer 403 corresponds to the blue light-emitting element. Moreover, the first angle adjustment layer 401 has a reflectance of more than 80% for light with a wavelength range of 620 nm to 760 nm and an incident angle of 0 to 20 degrees, a reflectance of 45% to 60% for light with a wavelength range of 620 nm to 760 nm and an incident angle of 20 to 35 degrees, and a reflectance of 40% or less for light with a wavelength range of 620 nm to 760 nm and an incident angle of 35 to 90 degrees. The second angle adjustment layer 402 has a reflectance of more than 80% for light with a wavelength range of 490 nm to 577 nm and an incident angle of 0 to 20 degrees, a reflectance of 45% to 60% for light with a wavelength range of 490 nm to 577 nm and an incident angle of 20 to 35 degrees, and a reflectance of 40% or less for light with a wavelength range of 490 nm to 577 nm and an incident angle of 35 to 90 degrees. The third angle adjustment layer 403 has a reflectance of more than 80% for light with a wavelength range of 420 nm to 480 nm and an incident angle of 0 to 20 degrees, a reflectance of 45% to 60% for light with a wavelength range of 420 nm to 480 nm and an incident angle of 20 to 35 degrees, and a reflectance of 40% or less for light with a wavelength range of 420 nm to 480 nm and an incident angle of 35 to 90 degrees. Referring to FIG. 18, when all of the three light-emitting elements are blue light-emitting elements, the structure of the angle adjustment layer 400 disposed on each light-emitting element and the reflectance at various angles of light are the same, that is, the angle adjustment layer 400 corresponding to each light-emitting element is the same angle adjustment layer 400. The angle adjustment layer 400 has a reflectance of more than 80% for light with a wavelength range of 420 nm to 480 nm and an incident angle of 0 to 20 degrees, a reflectance of 45% to 60% for light with a wavelength range of 420 nm to 480 nm and an incident angle of 20 to 35 degrees, and a reflectance of 40% or less for light with a wavelength range of 420 nm to 480 nm and an incident angle of 35 to 90 degrees.

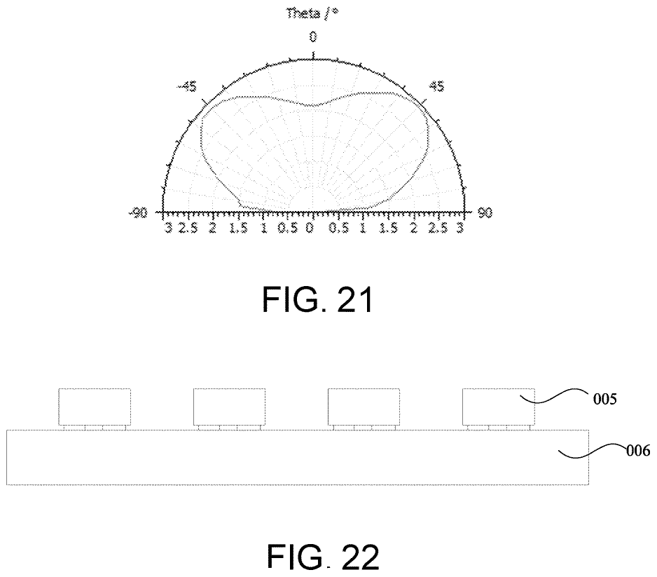

Referring to FIG. 20, the light-emitting angle in Embodiment 1 is only between −65° and +60°, whereas in this embodiment, through the arrangement of the angle adjustment layer 400 described above, the light-emitting angle range of each light-emitting element may reach a range between −80° and +80°, as shown in FIG. 21.

Optionally, each angle adjustment layer 400 is a DBR reflective layer, and the DBR reflective layer is formed by alternately stacking materials with different refractive indices. The material of the DBR reflective layer is at least two of different materials among SiO₂, TiO₂, ZnO₂, ZrO₂, and Cu₂O₃. In this embodiment, the DBR reflective layer may have a structure of alternately stacked TiO₂ layers/SiO₂ layers. Each layer may have an optical thickness of ¼ of a specific wavelength, and may be formed into 4 to 20 pairs. The specific DBR reflective layer structure may be designed with the reflectance of the required angle range or wavelength range, which will not be repeated here.

In a specific embodiment of this embodiment, referring to FIG. 16a, the three light-emitting elements of the light-emitting device are respectively a red light-emitting element, a green light-emitting element, and a blue light-emitting element, and the angle adjustment layer 400 includes a first angle adjustment layer 401, a second angle adjustment layer 402, and a third angle adjustment layer 403. The adhesive layer 300 includes a plurality of openings 301, and one angle adjustment layer 400 is embedded in each of the openings 301.

In a specific embodiment of this embodiment, referring to FIG. 17, the three light-emitting elements of the light-emitting device are respectively a red light-emitting element, a green light-emitting element, and a blue light-emitting element, and the angle adjustment layer 400 includes the first angle adjustment layer 401, the second angle adjustment layer 402, and the third angle adjustment layer 403, and each angle adjustment layer 400 is disposed on a surface of the adhesive layer 300 close to the plurality of light-emitting elements.

In a specific embodiment of this embodiment, referring to FIG. 18, the three light-emitting elements of the light-emitting device are all blue light-emitting elements, and the angle adjustment layer 400 corresponding to each light-emitting element is the same, and each angle adjustment layer 400 is disposed on the surface of the adhesive layer 300 close to the plurality of light-emitting elements.

In a specific embodiment of this embodiment, referring to FIG. 19, the three light-emitting elements of the light-emitting device are respectively a red light-emitting element, a green light-emitting element, and a blue light-emitting element, and the angle adjustment layer 400 includes the first angle adjustment layer 401, the second angle adjustment layer 402, and the third angle adjustment layer 403. Moreover, each angle adjustment layer 400 is disposed on the transparent layer 100, and the adhesive layer 300 covers the angle adjustment layer 400 and the transparent layer 100 between adjacent angle adjustment layers 400. The three light-emitting elements are formed on the adhesive layer 300, and correspond to the first angle adjustment layer 401, the second angle adjustment layer 402, and the third angle adjustment layer 403 one by one. Optionally, an area of each angle adjustment layer is greater than an area of each light-emitting element, so as to facilitate angle adjustment of the lateral light emission of the light-emitting elements.

It should be noted that any two or more of the above Embodiments 1 to 5 may be combined, for example, by applying any insulating layer structure described in Embodiment 1 to Embodiment 2, or applying the filling structure in Embodiment 2 to Embodiment 3, 4, or 5, or applying Embodiments 2 to 5 simultaneously to Embodiment 1, etc., and other combinations will not be enumerated one by one here.

### Embodiment 6

This embodiment provides a display device, referring to FIG. 22, the display device includes a display substrate 005 and at least one light-emitting device 006 formed on the display substrate 005. The light-emitting device may fix the wiring layer to the display substrate 005 and form an electrical connection by means of solder paste or the like, or may form a protective electrode on the wiring layer, and then fix the protective electrode to the display substrate 005 and form an electrical connection by means of solder paste or the like. The light-emitting device is the light-emitting device described in any one of the above Embodiments 1 to 5, or any combination of the above embodiments. Similarly, the light-emitting device has the technical effects of the above light-emitting device.

The above embodiments are merely illustrative of the principles and efficacy of the present disclosure, and are not intended to limit the present disclosure. Any person familiar with this technology may modify or change the above embodiments without departing from the spirit and scope of the present disclosure. Therefore, all equivalent modifications or changes completed by persons with ordinary knowledge in the relevant technical field without departing from the spirit and technical ideas disclosed in the present disclosure shall still be covered by the claims of the present disclosure.

What is claimed is:

1. A light-emitting device, comprising:
a plurality of light-emitting elements, the plurality of light-emitting elements being spaced apart;
a wiring layer, formed on the plurality of light-emitting elements, and electrically connected to the light-emitting elements;
an insulating layer, formed on the wiring layer, the insulating layer having an opening portion exposing a partial surface of the wiring layer;
a protective electrode, formed on the wiring layer, and forming an electrical connection with the wiring layer.

2. The light-emitting device according to claim 1, wherein an opening portion of the insulating layer comprises a lower surface in contact with the wiring layer, an upper surface opposite to the lower surface, and a side surface connecting the upper surface and the lower surface, wherein an angle between the side surface and the lower surface is less than or equal to 80°.

3. The light-emitting device according to claim 2, wherein the protective electrode comprises a first portion formed on the wiring layer and a second portion formed on the side surface of the opening portion of the insulating layer.

4. The light-emitting device according to claim 3, wherein a thickness of the first portion is greater than a thickness of the second portion.

5. The light-emitting device according to claim 1, wherein the protective electrode comprises a first-layer structure and a second-layer structure formed on the first-layer structure, and a thickness of the first-layer structure is greater than a thickness of the second-layer structure.

6. The light-emitting device according to claim 1, wherein a thickness of the protective electrode is less than a thickness of the insulating layer.

7. The light-emitting device according to claim 6, wherein there is a minimum distance D1 between a surface of the protective electrode and the upper surface of the insulating layer, the thickness of the insulating layer is H1, and a height difference between the D1 and the H1 is between 0 μm and 10 μm.

8. The light-emitting device according to claim 1, wherein a thickness of the protective electrode is between 1 μm and 6 μm, and a thickness of the insulating layer is between 2 μm and 10 μm.

9. The light-emitting device according to claim 1, wherein the wiring layer comprises copper metal, a portion of the copper metal is in contact with the insulating layer, and the portion of the copper metal is in contact with the protective electrode.

10. A light-emitting device, comprising:
a plurality of light-emitting elements, the plurality of light-emitting elements being spaced apart;
a wiring layer, formed on the plurality of light-emitting elements, and electrically connected to the light-emitting elements;
a protective electrode, formed on the wiring layer, and forming an electrical connection with the wiring layer;
an insulating layer, formed on the wiring layer, the insulating layer having an opening portion exposing a surface of the protective electrode;
wherein, the insulating layer covers a partial surface of the wiring layer, a partial surface and a sidewall of the protective electrode.

11. The light-emitting device according to claim 10, wherein there is a distance between an edge of the insulating layer covering the partial surface of the protective electrode and an edge of the protective electrode, and the distance is between 0 μm and 10 μm.

12. The light-emitting device according to claim 10, wherein the sidewall of the protective electrode is an uneven structure.

13. The light-emitting device according to claim 10, wherein the wiring layer comprises a first region connected to the light-emitting element, a second region forming the protective electrode, and a third region connecting the first region and the second region.

14. The light-emitting device according to claim 10, wherein the wiring layer comprises copper metal, the protective electrode comprises gold metal, the copper metal is in contact with the insulating layer, and a partial surface of the gold metal is in contact with the insulating layer.

15. The light-emitting device according to claim 1, wherein,
a transparent layer;
an adhesive layer, disposed above the transparent layer, the plurality of light-emitting elements being spaced apart on the adhesive layer;
a filling layer, filled between the adjacent light-emitting elements.

16. A display device, comprising:
a display substrate;
at least one light-emitting device, disposed on a surface of the display substrate, of the light-emitting device forms an electrical connection with the display substrate, and the light-emitting device is the light-emitting device according to claim 1.
